(19) United States
(12) Patent Application Publication
(10) Pub. No.: US 2011/0048771 A1
(43) Pub. Date: Mar. 3, 2011

(54) ELECTRONIC APPARATUS AND FLEXIBLE SUBSTRATE WIRING METHOD

(75) Inventors: Sachiko SATOMI, Kawasaki (JP); Tetsuyuki Kubota, Kawasaki (JP)

(73) Assignee: FUJITSU LIMITED, Kawasaki-shi (JP)

(21) Appl. No.: 12/868,133

(22) Filed: Aug. 25, 2010

(30) Foreign Application Priority Data
Aug. 26, 2009 (JP) 2009-195282

(51) Int. Cl. H05K 1/00; H05K 13/00

(52) U.S. Cl. 174/254; 29/829

(57) ABSTRACT

An electronic apparatus includes: a flexible substrate including, a first portion having a first wiring pattern, and a second portion connected to the first portion and having a second wiring pattern whose pattern width is wider than a pattern width of the first wiring pattern, wherein the second portion is supported by the first portion; a support unit configured to support the first portion of the flexible substrate; a first circuit unit connected to one of the first and second portions; and a second circuit unit connected to the first circuit unit via the first portion and second wiring patterns.

### CROSS-REFERENCE TO RELATED APPLICATION

This application is based upon and claims the benefit of priority from the prior Japanese Patent Application No. 2009-195282 filed on Aug. 26, 2009, the entire contents of which are incorporated herein by reference.

### FIELD

An embodiment discussed herein relates to a flexible substrate provided in an electronic apparatus.

### BACKGROUND

In the field of flex-rigid circuit boards, there exists technology capable of preventing substrate deformations, circuit disconnections, and the formation of waves, which can easily occur at the sites of flexion. Meanwhile, in the field of multilayer circuit boards, there exists technology for matching impedance among wiring patterns.

Since flexible substrates bend, it is necessary to secure certain mechanical characteristics, such as those related to strength and operability. However, it is difficult to adjust the thickness of wiring patterns or add additional layers to a flexible substrate in order to achieve higher-frequency transmission through the substrate, because doing so changes the mechanical characteristics of the flexible substrate.

### SUMMARY

According to an aspect of an embodiment, an electronic apparatus includes: a flexible substrate including, a first portion having a first wiring pattern, and a second portion connected to the first portion and having a second wiring pattern whose pattern width is wider than a pattern width of the first wiring pattern, wherein the second portion is supported by the first portion; a support unit configured to support the first portion of the flexible substrate; a first circuit unit connected to one of the first and second portions; and a second circuit unit connected to the first circuit unit via the first portion and second wiring patterns.

It is to be understood that both the foregoing summary description and the following detailed description are explanatory as to some embodiments of the present invention, and not restrictive of the present invention as claimed.

### BRIEF DESCRIPTION OF THE DRAWINGS

FIG. 1 is a plan view of the interior of a hard disk drive;

FIG. 2 is a plan view of the metal plate side of a flexible substrate;

FIG. 3 is a diagram for explaining wiring pattern widths in the metal attachment portions and point-to-point wiring of a flexible substrate;

FIG. 4 is a cross-section taken along the line B-B in FIG. 3;

FIG. 5 is a cross-section taken along the line C-C in FIG. 3;

FIG. 6 is a graph expressing the relationship between the wiring pattern width in a metal attachment portion and point-to-point wiring, and the characteristic impedance;

FIG. 7 is a flowchart of a flexible substrate wiring process;

FIG. 8 is a block diagram of a flexible substrate design apparatus;

FIG. 9 is a diagram for explaining wiring pattern widths in the metal attachment portions and point-to-point wiring of a flexible substrate;

FIG. 10 is a graph expressing the transmission characteristics of a flexible substrate provided as a comparative example;

FIG. 11 is a graph expressing the transmission characteristics of a flexible substrate;

FIG. 12 is a diagram for explaining wiring pattern shapes at the boundary portion between the metal attachment portions and the point-to-point wiring;

FIG. 13 is a front view of a mobile phone handset provided with a flexible substrate; and

FIG. 14 illustrates a cross-section taken along the line D-D in FIG. 13.

### DESCRIPTION OF EXAMPLE EMBODIMENTS

In the figures, dimensions and/or proportions may be exaggerated for clarity of illustration. It will also be understood that when an element is referred to as being “connected to” another element, it may be directly connected or indirectly connected, i.e., intervening elements may also be present. Further, it will be understood that when an element is referred to as being “between” two elements, it may be the only element layer between the two elements, or one or more intervening elements may also be present.

Hereinafter, embodiments of the present invention will be described with reference to the accompanying drawings.

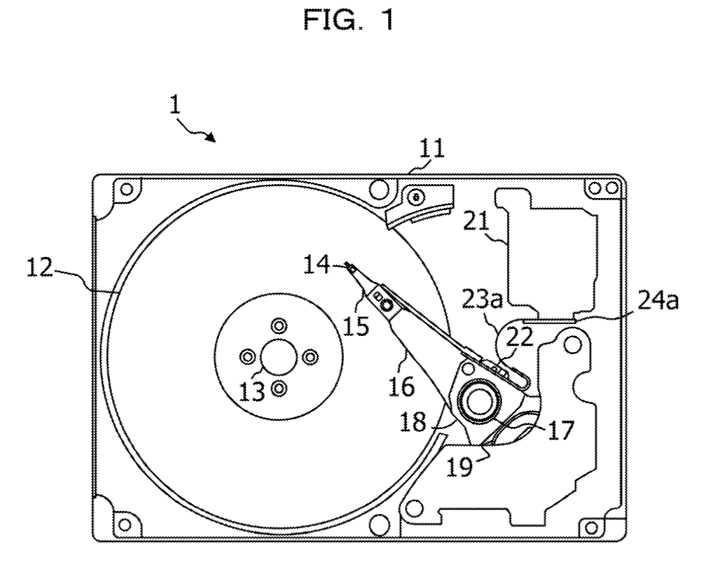

By way of example, a present embodiment will be described for the case of being applied to a hard disk drive (HDD) apparatus, hereinafter “HDD” for short. However, it should be appreciated that the technology disclosed in the present embodiment is also applicable to apparatuses or devices other than HDDs, such mobile phones or other electronic apparatuses having flexible substrates mounted therein. FIG. 1 is a plan view of the interior of an HDD 1. The HDD 1 includes a magnetic disk 12, a spindle motor 13, a head slider 14, head suspension 15, an arm 16, bearings 17, an actuator block 18, and a voice coil motor (VCM) 19, all housed inside a hard drive assembly 11. The magnetic disk 12 stores data. The spindle motor 13 rotationally drives the magnetic disk 12. The head slider 14 includes a head, which reads and writes data from and to the magnetic disk 12. The head suspension 15 supports the head slider 14. The arm 16 supports the head suspension 15. The VCM 19 rotationally drives the actuator block 18. The arm 16 rotates in accordance with the rotation of the actuator block 18.

The HDD 1 additionally includes a flexible substrate mounted therein. The flexible substrate includes regions whereupon a controller circuit 21 and an amp circuit 22 are mounted, as well as point-to-point wiring 23a. The controller circuit 21 sends write signals to the amp circuit 22, and receives read signals from the amp circuit 22. The amp circuit 22 includes a preamp (e.g., an amp IC) that amplifies write signals and read signals. The region whereupon the controller circuit 21 is mounted is affixed to the hard drive assembly 11, while the region whereupon the amp circuit 22 is mounted is affixed to the actuator block 18. Since the point-to-point wiring 23a bends in accordance with the rotation of the actuator block 18, the point-to-point wiring 23a is not fixed in place, and is highly flexed in a curved shape.

The circuitry related to write signals will now be described. The controller circuit 21 includes a write signal driver. The amp circuit 22 includes a read signal receiver. The receiver may be a preamp, for example. A write signal output from the driver in the controller circuit 21 is transmitted to the amp circuit 22 via the point-to-point wiring 23a. The write signal transmitted to the amp circuit 22 is amplified by the receiver inside the amp circuit 22.

A lid (not shown) is attached to the hard drive assembly 11, thus creating a hermetically sealed space. The magnetic disk 12, the spindle motor 13, the head slider 14, the head suspension 15, the arm 16, the bearings 17, the actuator block 18, the VCM 19, the amp circuit 22, and the point-to-point wiring 23a exist inside this hermetically sealed space. The controller circuit 21 exists outside this hermetically sealed space. A metal plate 24a is affixed to the hard drive assembly 11. By sealing off the boundary portion between the inside and the outside of the hermetically sealed space, the metal plate 24a keeps the hermetically sealed space airtight. The metal plate 24a may be realized by a metal such as stainless steel, for example.

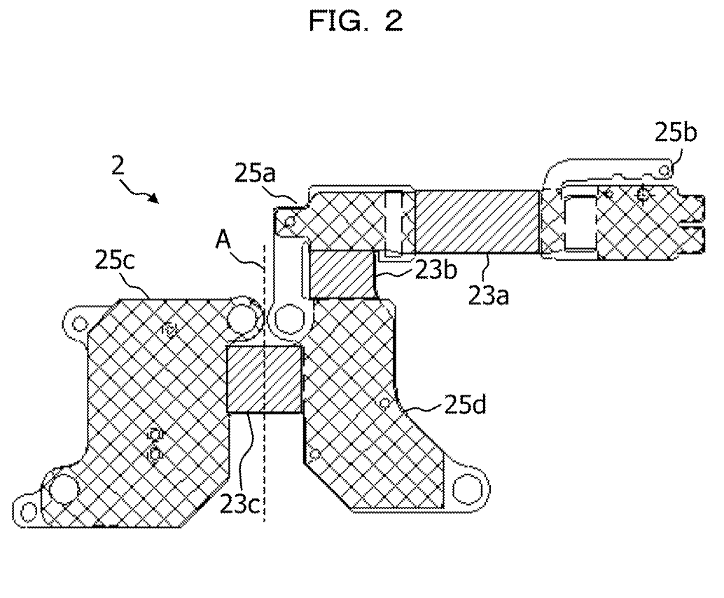

Hereinafter, a flexible substrate will be described using FIGS. 2 to 5. The flexible substrate described herein has metal plates attached on only one side thereof. This side is referred to as the metal plate side. In addition, wiring patterns are formed on the side opposite the metal plate side. This side is referred to as the wiring side.

FIG. 2 is a plan view of the metal plate side. The reference number 2 in FIG. 2 refers to the flexible substrate. The cross-hatched portions 25a to 25d indicate metal attachment portions where metal plates are attached. The metal plate 24a illustrated in FIG. 1 is attached to the metal attachment portion 25a to support the metal attachment portion 25a. The amp circuit 22 is mounted on the metal attachment portion 25b. The wiring sides of the metal attachment portions 25c and 25d are bent along the fold A and joined together. The controller circuit 21 is disposed on the metal attachment portions 25c and 25d in this joined state. Between the metal attachment portions 25a-25b, 25a-25d, and 25c-25d, point-to-point wiring 23a, 23b, and 23c is respectively interposed. The metal attachment portion 25a is supported by the metal plate 24a, and affixed to the hard drive assembly 11 via the metal plate 24a. The point-to-point wiring 23a to 23c are respectively supported by the metal attachment portions 25a to 25d. It should be appreciated that the flexible substrate 2 is not limited to the shape illustrated in FIG. 2. Next, the wiring patterns in the metal attachment portions 25a and 25b as well as in the point-to-point wiring 23a will be described.

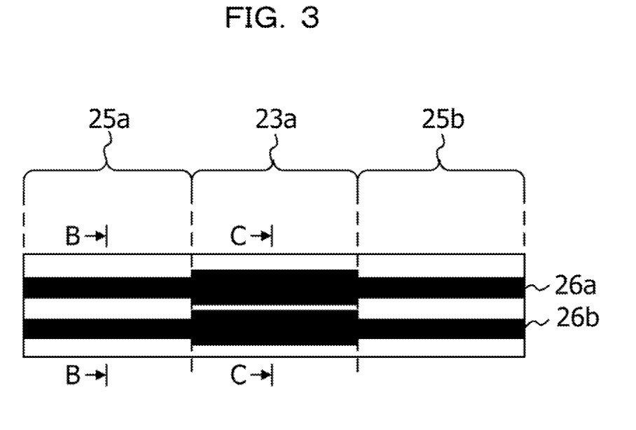

FIG. 3 is a diagram for explaining wiring pattern widths in the metal attachment portions 25a and 25b as well as the point-to-point wiring 23a of the flexible substrate 2. The reference numbers 26a and 26b illustrated in FIG. 3 indicate wiring patterns, upon which write signals are transmitted.

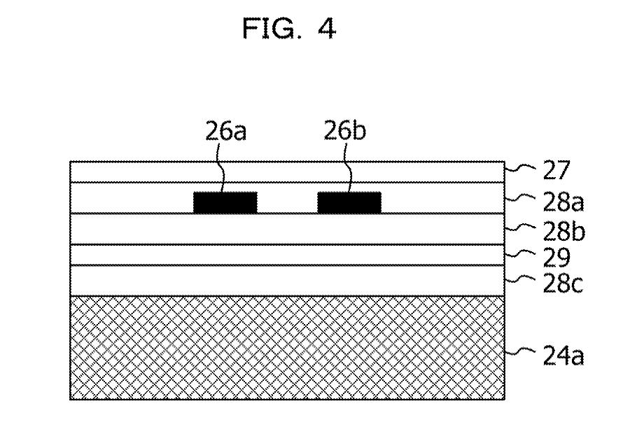

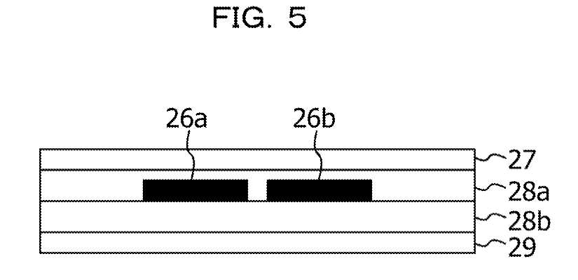

FIGS. 4 and 5 are cross-sections taken along the lines B-B and C-C in FIG. 3, respectively. The wiring patterns 26a and 26b are mounted on a base layer 29 via an adhesive layer 28b. In addition, a cover layer or similarly surface-protecting layer 27 covers the wiring patterns 26a and 26b via an adhesive layer 28a. The metal plate 24a is attached to the base layer 29 of the flexible substrate 2 via an adhesive layer 28c. As illustrated in FIGS. 3 to 5, the pattern widths of the wiring patterns 26a and 26b differ for the metal attachment portions 25a and 25b versus the point-to-point wiring 23a. By adjusting the respective pattern widths for the metal attachment portions 25a and 25b versus the point-to-point wiring 23a, the characteristic impedance of the wiring patterns between the driver and receiver can be matched, while leaving the mechanical characteristics of the flexible substrate 2 almost entirely unchanged. It should be appreciated that the impedance of the driver and the receiver may also be matched. Moreover, both the impedance of the driver and the receiver, as well as the characteristic impedance of the wiring patterns between the driver and receiver, may also be matched.

In order to match the characteristic impedance, the thicknesses of the surface-protecting layer 27, the base layer 29, and the individual adhesive layers may be altered, or alternatively, the thicknesses of the wiring patterns 26a and 26b may be altered. However, if such thicknesses are altered, then the flexibility, strength, and other mechanical characteristics of the flexible substrate 2 will change. Therefore, it is preferable to adjust the pattern widths such that the mechanical characteristics of the flexible substrate 2 remain unchanged, and thereby match the characteristic impedance without altering the thicknesses of the surface-protecting layer 27, the base layer 29, the individual adhesive layers, or the wiring patterns 26a and 26b.

Ideally, the pattern widths of the wiring patterns 26a and 26b for the metal attachment portions 25a and 25b as well as the point-to-point wiring 23a should be adjusted such that the characteristic impedance becomes equal to the impedance of the receiver and the driver. Herein, it should be appreciated that wiring patterns other than the wiring patterns 26a and 26b may also be collected in the metal attachment portions 25a and 25b as well as in the point-to-point wiring 23a. Since modifying the pitch of the wiring patterns 26a and 26b will affect the wiring pitch of other collected wiring patterns, it is possible that the design of the wiring patterns themselves may need to be re-evaluated. Consequently, it is preferable to adjust the pattern widths of the wiring patterns 26a and 26b without modifying the pattern pitch. In addition, there exist pattern width constraints for preserving the mechanical characteristics of the flexible substrate 2 against fabrication problems and vibrations. If the pattern widths are not at least substantially equal to the lower-bound values of these constraints, then disconnections might occur in the wiring patterns 26a and 26b. Thus, the pattern widths of the wiring patterns 26a and 26b should satisfy the constraints.

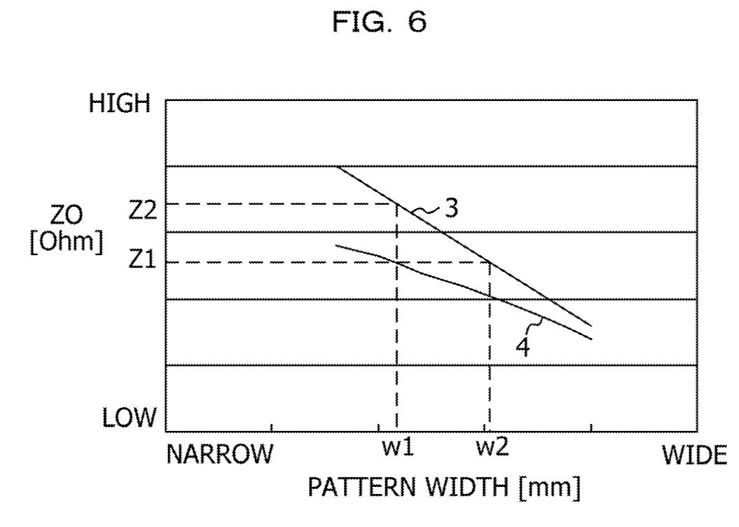

FIG. 6 is a graph expressing the relationship between the pattern widths of the wiring pattern 26a in the metal attachment portion 25a and the point-to-point wiring 23a, and the characteristic impedance. In FIG. 6, the vertical axis Zo expresses the characteristic impedance in units of ohms, while the horizontal axis expresses the pattern width of the wiring pattern 26a in units of millimeters. The line 3 expresses the relationship between the pattern width in the point-to-point wiring 23a and the characteristic impedance. The line 4 expresses the relationship between the pattern width in the metal attachment portion 25a and the characteristic impedance. As illustrated in FIG. 6, when the wiring pattern 26a of the metal attachment portion 25a and the point-to-point wiring 23a has an equal pattern width w1, the characteristic impedance is higher for the point-to-point wiring 23a. Here, the pattern width in the point-to-point wiring 23a can be altered to the pattern width w2, where the characteristic impedance is equal to that of the metal attachment portion 25a. In so doing, the characteristic impedance for the metal attachment portion 25a and the point-to-point wiring 23a can be set to the same value Z1. For example, the pattern width w2 may be wider than the pattern width w1 by a factor of approximately 1.5 to 2.0. Hereinafter, a method of wiring a flexible substrate will be described in detail, wherein pattern widths are determined for the wiring patterns 26a and 26b in the metal attachment portions 25a and 25b as well as the point-to-point wiring 23a.

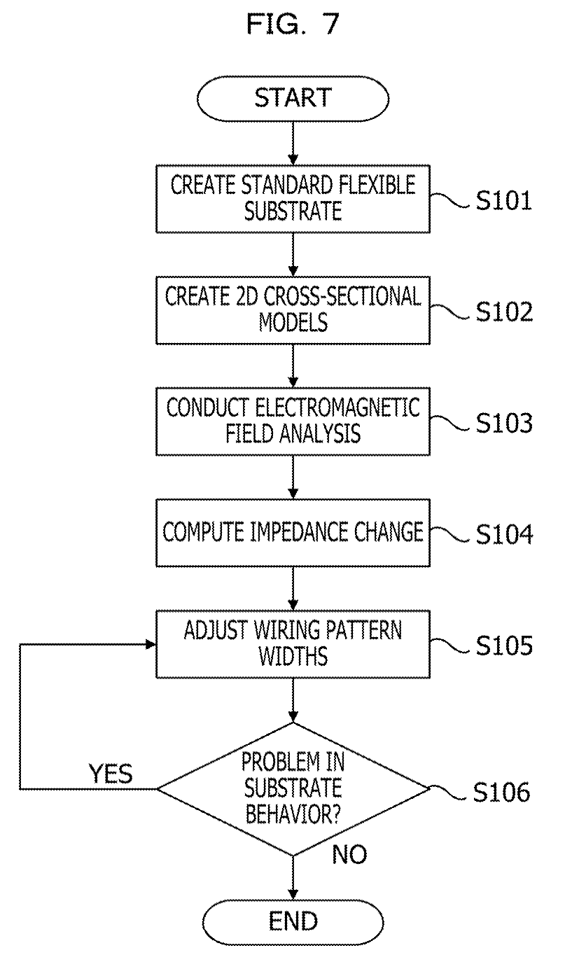

FIG. 7 is a flowchart of a flexible substrate wiring process. Herein, an electromagnetic field numerical simulation using the finite element method is used as the method for computing the relationship between the pattern width and the characteristic impedance. The relationship between the pattern width and the characteristic impedance may also be computed by some other electromagnetic field numerical simulation or analysis. The computation results may also be interpolated by the least-squares or other method, and the interpolated results used as the relationship between the pattern width and the characteristic impedance.

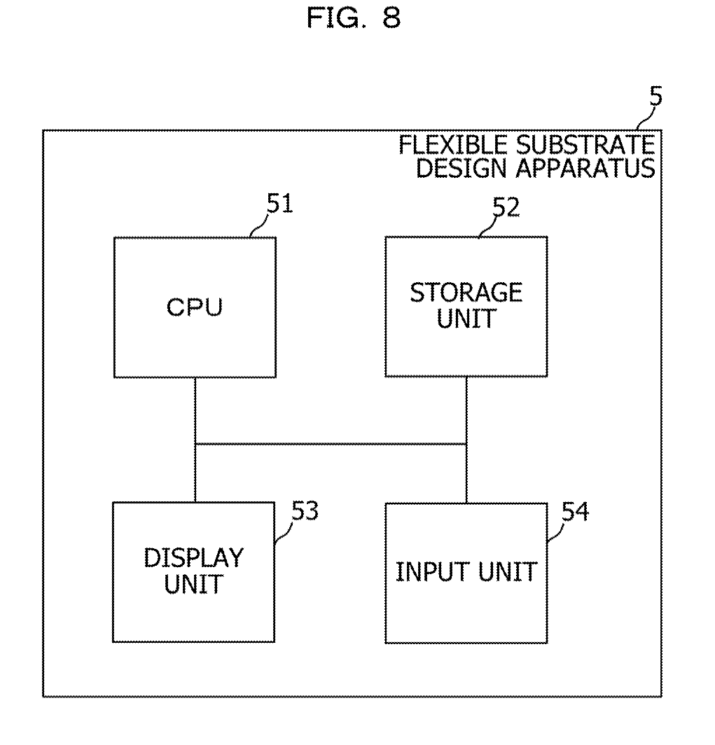

FIG. 8 is a block diagram of a flexible substrate design apparatus that executes operations for wiring a flexible substrate. The flexible substrate design apparatus 5 is realized with a computer, for example. This computer includes a central processing unit (CPU) 51, a storage unit 52, a display unit 53, and a keyboard or other input unit 54. A program that executes a flexible substrate wiring method is stored in the storage unit 52. This program causes the CPU 51 to execute a flexible substrate design method. Herein, the storage unit 52 may be an HDD, a random access memory (RAM), or any other memory device suitable for storing program(s) to be readable and executed by the CPU 51, for example. The display unit 53 is a monitor or other display device that displays information such as flexible substrate design schematics and two-dimensional cross-sectional models, for example.

First, as a result of instructions issued by the user via the input unit 54, the CPU 51 designs a flexible substrate (S101) as shown in FIG. 7. In this design, wiring patterns having standard pattern widths are positioned in the flexible substrate. Among the positioned wiring patterns, the wiring patterns 26a and 26b in the metal attachment portions 25a and 25b as well as the point-to-point wiring 23a are set having substantially equal pattern widths. After designing, the CPU 51 creates 2D cross-sectional models of the metal attachment portions 25a and 25b as well as the point-to-point wiring 23a in the flexible substrate 2 (S102). At this point, it is assumed that the metal attachment portion 25a and the metal attachment portion 25b have similar cross-sectional configurations, and thus a 2D cross-sectional model is created for just the metal attachment portion 25a. More specifically, in the electromagnetic field numerical simulation, the CPU 51 creates a 2D model of a cross-section of the metal attachment portion 25a like that illustrated in FIG. 4, for example. Similarly, in the electromagnetic field numerical simulation, the CPU 51 creates a 2D model of a cross-section of the point-to-point wiring 23a like that illustrated in FIG. 5, for example. The CPU 51 then conducts electromagnetic field analysis with respect to each of the 2D cross-sectional models thus created (S103). After conducting the electromagnetic field analysis, the CPU 51 computes the relationships between the pattern widths of the wiring patterns 26a and 26b, respectively, for the metal attachment portions 25a and 25b versus the characteristic impedance. Similarly, the CPU 51 respectively computes the relationships between the pattern widths of the wiring patterns 26a and 26b for the point-to-point wiring 23a versus the characteristic impedance (S104). The computation results may be a graph like that illustrated in FIG. 6, for example.

After computation, the CPU 51 uses the computation results as a basis for setting the respective pattern widths for the wiring patterns 26a and 26b in the metal attachment portions 25a and 25b as well as the point-to-point wiring 23a (S105). More specifically, the CPU 51 sets the characteristic impedance respectively for the wiring patterns 26a and 26b in the metal attachment portions 25a and 25b as well as the point-to-point wiring 23a, such that the characteristic impedance is as close as possible to the impedance of the receiver. The CPU 51 then sets pattern widths corresponding to this characteristic impedance in the metal attachment portions 25a and 25b, respectively, as well as the point-to-point wiring 23a. In other words, the characteristic impedance is matched among the metal attachment portions 25a and 25b as well as the point-to-point wiring 23a.

After setting the pattern widths, the CPU 51 conducts circuit analysis of the flexible substrate as a whole, including circuits near the point-to-point wiring 23a (e.g., all wiring patterns in the flexible substrate), and checks whether any problems exist in the behavior (for example, the transmission characteristics or other aspects of signal quality) of the flexible substrate (S106). If there are no problems in the behavior of the flexible substrate (S106, No), then the present flow is terminated.

In contrast, if a problem does exist in the behavior of the flexible substrate 2 (S106, Yes), then the CPU 51 once again executes the processing for adjusting the wiring pattern widths in operation S105. In this case, the set pattern widths may be re-adjusted, and the set characteristic impedance may be re-adjusted. This circuit analysis may be conducted using a circuit simulation, for example.

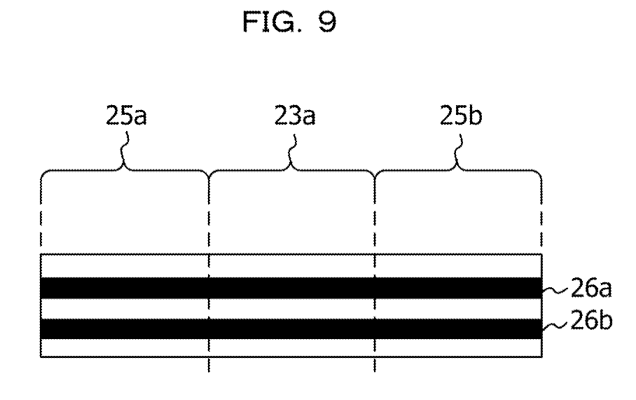

Next, the transmission characteristics of the flexible substrate 2 will be compared to the transmission characteristics of a flexible substrate 2a (not illustrated), herein given as a comparative example. In the flexible substrate 2a, the pattern widths of the wiring patterns 26a and 26b in the point-to-point wiring 23a are equal to those in the metal attachment portions 25a and 25b. First, the pattern widths of the wiring patterns 26a and 26b in the metal attachment portions 25a and 25b as well as the point-to-point wiring 23a will be described. FIG. 9 is a schematic diagram for explaining the pattern widths of the wiring patterns 26a and 26b in the metal attachment portions 25a and 25b as well as the point-to-point wiring 23a of the flexible substrate 2a. As illustrated in FIG. 9, in the flexible substrate 2a, the pattern widths of the wiring patterns 26a and 26b are equal for the metal attachment portions 25a and 25b as well as the point-to-point wiring 23a.

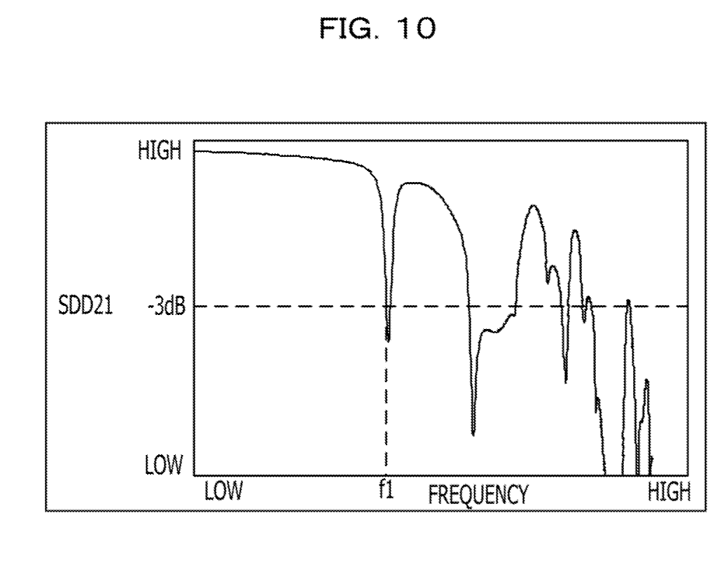

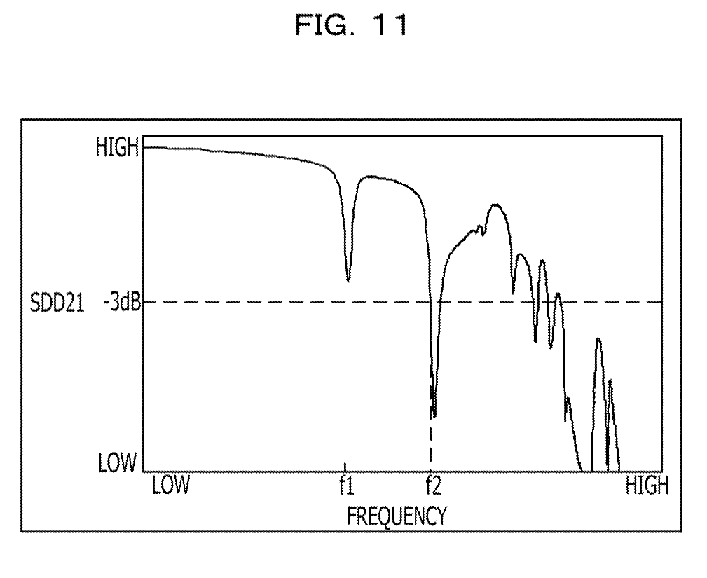

FIG. 10 is a graph expressing the transmission characteristics of the flexible substrate 2a given herein as a comparative example. FIG. 11 is a graph expressing the transmission characteristics of the flexible substrate 2. In FIGS. 10 and 11, the vertical axis expresses the value of the differential mode SDD21, while the horizontal axis expresses the frequency. Herein, the transmission characteristics illustrated in FIGS. 10 and 11 are the transmission characteristics from the driver to the receiver. The frequency at which the SDD21 becomes −3 dB is herein taken to be the fundamental frequency, for example.

The fundamental frequency of the flexible substrate 2a is f1. The fundamental frequency of the flexible substrate 2 is f2. The frequency f2 is higher than the frequency f1. Accordingly, the pattern width of the point-to-point wiring 23a is set such that its characteristic impedance matches the characteristic impedance of the wiring patterns 26a and 26b in the metal attachment portions 25a and 25b. In so doing, the frequency that attenuates at −3 dB can be increased. Consequently, improved transmission characteristics can be anticipated.

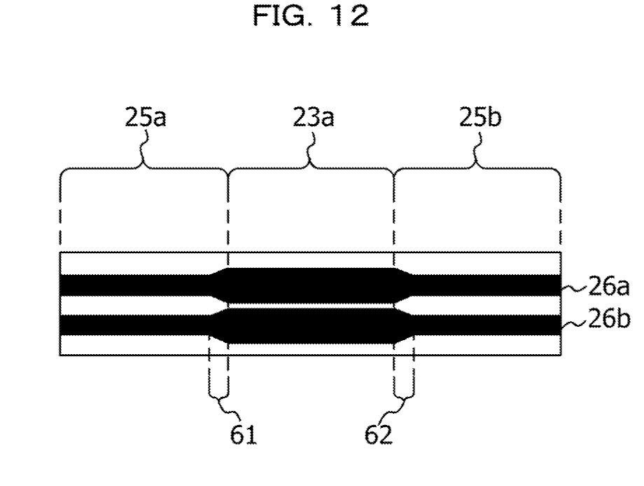

Meanwhile, as illustrated in FIG. 3, the shapes of the wiring patterns 26a and 26b undergo a sudden change in pattern width at the boundary where the metal attachment portions 25a and 25b become the point-to-point wiring 23a. However, as illustrated in FIG. 12, the pattern width of the metal attachment portion 25a may be altered at the boundary portion 61 where the metal attachment portion 25a becomes the point-to-point wiring 23a. The pattern width at the boundary portion 61 may be altered so that the pattern width of the metal attachment portion 25a is gradually increased in the layout direction, starting from the pattern width of the metal attachment portion 25a and increasing to the pattern width of the point-to-point wiring 23a. It is preferable to start increasing the pattern width at some point along the metal attachment portion 25a, such that the pattern width becomes equal to that of the point-to-point wiring 23a at the boundary with the point-to-point wiring 23a. However, the pattern width may also be increased so as to reach the pattern width of the point-to-point wiring 23a at some point within the point-to-point wiring 23a. Similar alterations may be made at the boundary portion 62 where the metal attachment portion 25b becomes the point-to-point wiring 23a.

Gradually increasing the pattern width of the wiring patterns 26a and 26b exhibits the effect of inhibiting the concentration of stress at the boundary portions 61 and 62. Herein, the shapes of the wiring patterns 26a and 26b at the boundary portions 61 and 62 are shaped so that any effects on the characteristic impedance and the transmission characteristics can be ignored, and may be appropriately set according to factors such as the width and thickness of the wiring patterns 26a and 26b.

This technique is executed as part of the wiring pattern adjustment process in operation S105. For example, after setting the pattern widths in the metal attachment portion 25a and the point-to-point wiring 23a, the CPU 51 may gradually increase the pattern width of the wiring pattern 26a, starting at a point along the metal attachment portion 25a. The CPU 51 makes the pattern width of the wiring pattern 26a equal to the pattern width of the point-to-point wiring 23a at the boundary where the metal attachment portion 25a becomes the point-to-point wiring 23a.

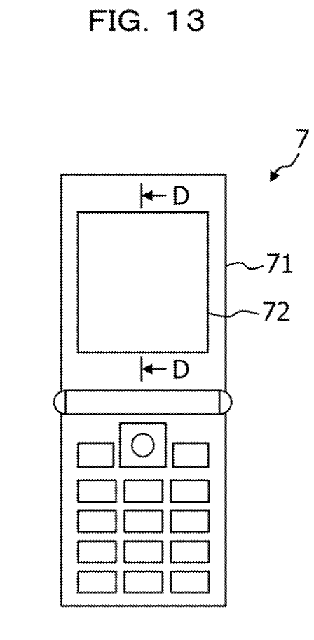

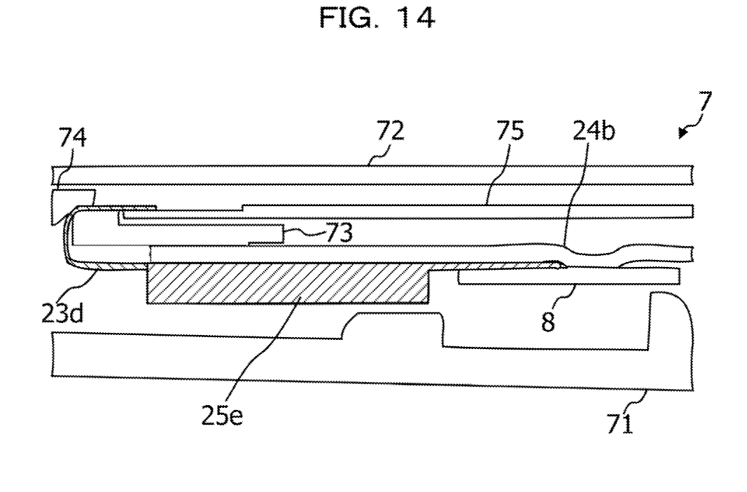

An HDD has been given as an example of an electronic apparatus, but the present embodiment is not limited thereto. For example, the present embodiment may also be an electronic apparatus such as a mobile phone handset. FIG. 13 is an exterior view of a mobile phone handset provided with a flexible substrate. FIG. 14 is a cross-section taken along the line D-D in FIG. 13. As illustrated in FIGS. 13 and 14, the mobile phone handset 7 is provided with a liquid crystal display (LCD) panel 72 in a chassis 71, with the flexible substrate included in its interior. The flexible substrate includes a metal attachment portion 25e and point-to-point wiring 23d. One end of the metal attachment portion 25e is connected to a rigid printed circuit board 8, and is attached to a metal plate 24b. The point-to-point wiring 23d is curved so as to be positioned between an LCD holder 73 and a rib 74 of the chassis 71. One end of the point-to-point wiring 23d is connected to a circuit on a rigid or flexible substrate included in an LCD glass 75. In this way, the present embodiment is also applicable to an electronic apparatus having a flexible substrate that includes a metal attachment portion and point-to-point wiring.

In the process for creating 2D cross-sectional models in operation S102, a 2D cross-sectional model of the metal attachment portion 25a is created. However, a 2D cross-sectional model of the metal attachment portion 25b may be created, or 2D cross-sectional models for both the metal attachment portions 25a and 25b may be created. In the process for computing an impedance change in operation S104, the characteristic impedance is computed with respect to the wiring patterns 26a and 26b. However, in cases where the wiring patterns 26a and 26b have identical structures, the characteristic impedance may be computed with respect to just one of either the wiring pattern 26a or the wiring pattern 26b, with the computation results being applied to the remaining wiring pattern. The above may be similarly applied to the wiring pattern width adjustment process in operation S105.

In the wiring pattern width adjustment process in operation S105, the computation results are described as being used as a basis for setting respective pattern widths for the wiring patterns 26a and 26b in the metal attachment portions 25a and 25b as well as the point-to-point wiring 23a. However, in the standard flexible substrate creation process in operation S101, the characteristic impedance of the pattern widths in the metal attachment portions 25a and 25b may be set to the value closest to the impedance of the receiver, and a flexible substrate may be designed with such pattern widths are the standard pattern widths. In this case, the pattern widths of the metal attachment portions 25a and 25b become fixed in the wiring pattern width adjustment process in operation S105, and only the pattern width of the point-to-point wiring 23a is set.

In the wiring pattern width adjustment process in operation S105, the respective characteristic impedance of the wiring patterns 26a and 26b in the metal attachment portions 25a and 25b as well as the point-to-point wiring 23a is described as being set to the characteristic impedance that is closest to the impedance of the receiver. However, the respective characteristic impedance of the wiring patterns 26a and 26b in the metal attachment portions 25a and 25b as well as the point-to-point wiring 23a may also be set to the characteristic impedance that is closest to the impedance of the driver. However, in this case, the impedance of the driver and the receiver may be matched.

In the standard flexible substrate creation process in operation S101, the characteristic impedance of the pattern width in the point-to-point wiring 23a may be set to the value closest to the impedance of the receiver, and a flexible substrate may be designed with this pattern width as the standard pattern width. In this case, the pattern width of the point-to-point wiring 23a becomes fixed in the wiring pattern width adjustment process in operation S105, and only the pattern widths of the metal attachment portions 25a and 25b are set. For example, the pattern width of the point-to-point wiring 23a may be fixed at the initially designed pattern width in the standard flexible substrate creation process in operation S101, and then reduced by a factor of approximately 0.5 to 0.8 to set the pattern widths of the wiring patterns 26a and 26b in the metal attachment portions 25a and 25b.

However, in the case of fixing the pattern widths of either the metal attachment portions 25a and 25b or the point-to-point wiring 23a, the design is subject to the conditions that the characteristic impedance be matched for the metal attachment portions 25a and 25b as well as the point-to-point wiring 23a, and that no problems occur in the fabrication of the flexible substrate 2. Similar conditions apply to the case of modifying both the pattern widths of the metal attachment portions 25a and 25b as well as the pattern width of the point-to-point wiring 23a.

Herein, the pattern widths to be modified are described as being the pattern widths of the wiring patterns 26a and 26b that transmit write signals. However, the widths of the wiring patterns that transmit read signals may also be modified. In addition, in cases where additional wiring patterns are formed in the point-to-point wiring 23a for purposes other than transmitting write signals or read signals, such wiring patterns may also be modified.

The pattern widths of the wiring patterns 26a and 26b are described as being modified for the metal attachment portions 25a and 25b as well as the point-to-point wiring 23a. However, the pattern widths of the wiring patterns 26a and 26b may be modified for the other metal attachment portions 25c and 25d as well as the point-to-point wiring 23b and 23c. In this case, the pattern widths may be modified for the wiring patterns 26a and 26b in a portion of the point-to-point wiring, without modifying the pattern widths of the wiring patterns 26a and 26b in the entire plurality of point-to-point wiring. Similarly, the pattern widths may be modified for the wiring patterns 26a and 26b in a portion of the metal attachment portions, without modifying the pattern widths of the wiring patterns 26a and 26b in the entire plurality of metal attachment portions.

Metal plates such as the metal plate 24a are described as being attached to one side of the flexible substrate 2. However, metal plates may be attached to both sides, and the wiring patterns 26a and 26b may be formed on both sides of the flexible substrate 2. Furthermore, although the metal plates are herein attached to the metal attachment portions 25a to 25d, the metal plates may also be provided in a joined state with the metal of the hard drive assembly 11 or the actuator block 18, for example, instead of being attached.

Due to increases in the transfer speeds of electronic apparatuses, such as the HDD 1, degradation of the transmission characteristics in the flexible substrates housed in such electronic apparatus becomes a problem. In the case of improving the transfer rate, it becomes necessary to raise the frequency of the transmission characteristics of the flexible substrate. There exists technology for adjusting the thickness of wiring patterns or adding additional layers to a flexible substrate in order to achieve impedance matching or techniques for higher-frequency transmission. If pattern thicknesses are adjusted or additional layers are added, then the mechanical characteristics of the flexible substrate will change. With flexible substrates that include areas such as the point-to-point wiring 23a, changing the mechanical characteristics is not desirable.

According to the present embodiment, the patterns widths of the wiring patterns 26a and 26b in the metal attachment portions 25a and 25b as well as the point-to-point wiring 23a are set to widths such that the characteristic impedance is matched. Accordingly, it becomes possible to improve transmission characteristics at higher frequencies, while leaving the mechanical characteristics almost entirely unchanged. By increasing the frequency of the transmission characteristics, signal quality is improved.

When additional layers are added to the flexible substrate 2 or the thicknesses of the wiring patterns 26a and 26b are adjusted in order to match the characteristic impedance, the number of fabrication steps and the change in the mechanical characteristics increases considerably. In contrast, with the adjustment of the widths of the wiring patterns 26a and 26b in the present embodiment, the increase in the number of fabrication steps and the change in the mechanical characteristics are decreased.

All examples and conditional language recited herein are intended for pedagogical purposes to aid the reader in understanding the invention and the concepts contributed by the inventor to furthering the art, and are to be construed as being without limitation to such specifically recited examples and conditions. Although the embodiments of the present inventions has been described in detail, it should be understood that various changes, substitutions, and alterations could be made hereto without departing from the spirit and scope of the invention.

What is claimed is:

1. An electronic apparatus comprising:
a flexible substrate including, a first portion having a first wiring pattern, and a second portion connected to the first portion and having a second wiring pattern whose pattern width is wider than a pattern width of the first wiring pattern, wherein the second portion is supported by the first portion;
a support unit configured to support the first portion of the flexible substrate;
a first circuit unit connected to one of the first and second portions; and
a second circuit unit connected to the first circuit unit via the first portion and second wiring patterns.

2. The electronic apparatus according to claim 1, wherein the first wiring pattern and the second wiring pattern have pattern widths based on predetermined relationships between the respective pattern widths and a characteristic impedance of the respective wiring patterns.

3. The electronic apparatus according to claim 1, wherein a characteristic impedance of the first wiring pattern and the second wiring pattern is matched to an impedance of the first circuit unit.

4. The electronic apparatus according to claim 1, wherein an impedance of the first circuit unit and the second circuit unit is matched.

5. The electronic apparatus according to claim 1, wherein, at a boundary where the first wiring pattern becomes the second wiring pattern, the pattern width is gradually increased from the width of the first wiring pattern toward the width of the second wiring pattern.

6. The electronic apparatus according to claim 1, wherein the support unit includes a metal plate that provides an airtight seal for a first space inside the electronic apparatus by sealing off boundary portions between the first space and a second space, different from the first space.

7. The electronic apparatus according to claim 1, wherein
the second circuit unit is a driver that transmits signals, and
the first circuit unit is a receiver that receives signals transmitted from the second circuit unit.

8. A flexible substrate wiring method, the flexible substrate including a first portion supported by a support unit and having a first wiring pattern, and a second portion supported by the first flexible substrate unit and having a second wiring pattern connected to the first wiring pattern, the method comprising:
computing predetermined relationships between a pattern width and a characteristic impedance of the first and second wiring patterns, respectively; and
setting the widths of the first wiring pattern and the second wiring pattern based on the computed predetermined relationships.

9. The flexible substrate wiring method according to claim 8, wherein the characteristic impedance of the first wiring pattern and the second wiring pattern is set based on an impedance of a first circuit unit connected to one of the first flexible substrate unit or the second flexible substrate unit.

10. The flexible substrate wiring method according to claim 9, wherein the impedance is matched between the first circuit unit and a second circuit unit connected to the first circuit unit via the first flexible substrate unit and the second flexible substrate unit.

11. The flexible substrate wiring method according to claim 8, wherein
an electromagnetic field numerical simulation is used to create 2D models of cross-sections of the first flexible substrate unit and the second flexible substrate unit, and
the predetermined relationships are computed by conducting electromagnetic field analysis with respect to the created 2D models.

12. The flexible substrate wiring method according to claim 8, wherein, at a boundary where the first wiring pattern becomes the second wiring pattern, the pattern width is gradually increased from the width of the first wiring pattern toward the width of the second wiring pattern.

13. The flexible substrate wiring method according to claim 9, wherein
before computing the predetermined relationships, the width of the first wiring pattern is set to a pattern width so that the characteristic impedance in the first wiring pattern becomes substantially equal to the impedance in the first circuit unit, and
only the width of the second wiring pattern is set based on the computed predetermined relationships.
